(19) United States
(12) Patent Application Publication
(10) Pub. No.: US 2010/0088970 A1
(43) Pub. Date: Apr. 15, 2010

(54) SMART MULTIFUNCTIONING BUILDING PANEL

(75) Inventor: Mark MILLER, San Francisco, CA (US)

Correspondence Address: Ashok K. Janah, 650 DELANCEY STREET, SUITE 106, SAN FRANCISCO, CA, 94107-2001, US

(73) Assignee: PROJECT FROG, INC., San Francisco, CA (US)

(21) Appl. No.: 12/617,713

(22) Filed: Nov. 12, 2009

Related U.S. Application Data
(60) Provisional application No. 61/114,726, filed on Nov. 14, 2008.

(51) Int. Cl. H01L 31/042; G08B 19/00; E04C 2/52; G08B 21/00; G08B 17/00

(52) U.S. Cl. 52/1; 52/220.1; 52/173.1; 340/540; 340/584

(57) ABSTRACT

A multifunctional panel for a building comprises an insulative body, an exterior surface, and an interior surface. A sensor is provided to measure an interior condition in the interior of the building and an exterior condition in the exterior of the building, and generate a sensor signal in response to the difference between the measured interior and exterior conditions. A signal coupler can transmit the sensor signal to other multifunctional panels, receive an input signal from another multifunctional panel, or pass power to power a device in or about the insulative body.

### RELATED APPLICATION

This application claims the benefit of Provisional Application No. 61/114,726, filed Nov. 14, 2008, which is incorporated by reference herein in its entirety.

### BACKGROUND

Embodiments of the present invention relate to a smart or multifunctional panel for buildings.

Modern buildings and building components that are intelligent and take the environment into consideration reduce the energy usage and carbon footprint of the building. With the increasing problems of climate change and environmental degradation, it is becoming more and more important for the building industry to become energy efficient and “green”. There is also an increasing need for buildings which have reduced environmental impacts in terms of the embodied energy usage and emissions, green construction materials and components, on-site construction, and the ultimate end-of-life reuse and/or recycling potential. Energy efficient buildings also reduce the energy required to operate a building without compromising the comfort levels of its occupants.

The exterior environment and layout of a building can also a significantly impact the energy consumed by the building. For example, in hot or summer environments, it may be desirable to allow hot air that accumulates within the building to escape from the interior of the building. Releasing heated air reduces the amount of energy required to cool the interior of the building. In contrast, in cold or winter environments, it may be desirable to prevent leakage of hot air from the building and thereby increase its energy efficiency. Controlling building functions based on the temperatures or other attributes of the sunny or shade side of the building can also affect energy consumption within the building. For example, the sunny side of a building can be at temperatures which are 2° to 8° C. higher than the shade side of the same building. When building air intake vents are located on the sunny side, in summer, air retrieved from that side of the building has to be cooled by an additional amount to reach the desired cool interior temperatures. Conversely, in winter, air retrieved from the shady side of the building has to be heated by an additional amount to reach the desired heated temperatures. An intelligent building that takes these factors into consideration in operating the building would save energy.

Still further, in some situations, it is also desirable to have buildings that can partially or entirely generate their own energy requirements. For example, in certain remote sites or at new construction sites, access to a main utility or power grid may not be available. In these sites, the construction or operation of conventional buildings requires the setup of large generators to power lights, heat, and communications equipment in the building, or construction tools used to assemble the building. However, such generators tend to be noisy and polluting, and require continuous supplies of combustible fuels in order to operate. The generators are also heavy to transport and their size and weight are proportional to their maximum load outputs. Even when a main grid power connection is available, an energy generating building can reduce its use of carbon fuels and lower operating costs. Thus, energy-producing building components are desirable to address these needs.

Yet another application of smart or intelligent building components occurs in the fabrication of modular buildings or buildings assembled on-site from predesigned building kits. Modular and kit buildings can be made from pre-fabricated structural members or panels that are designed and developed to facilitate shipment, assembly, and operation of a building. Predesigned components for modular or kit buildings reduce the fabrication and assembly costs for building structures that have a common purpose. Thus, building components such as panels and other structural members that facilitate shipping, assembly of the building, and design of the building can be useful.

For reasons including these and other deficiencies, and despite the development of many different building components, such as panels and other structural members, further improvements in such components are continuously being sought to improve the energy efficiency, ease of construction, and operation of modern buildings.

### SUMMARY

A multifunctional panel for a building comprises an insulative body, an exterior surface that is weather resistant, and an interior surface that opposes the weather resistant exterior surface. One or more sensors provided to measure an interior condition in the interior of the building and an exterior condition in the exterior of the building, and generate a sensor signal in response to the difference between the measured interior and exterior conditions. A signal coupler to transmit the sensor signal to other multifunctional panels, receive an input signal from another multifunctional panel, or pass power to power a device in or about the insulative body.

In another version, a multifunctional panel comprises an insulative body comprising an energy storage device having a pair of terminals and opposing interior and exterior surfaces, the exterior surface including a photovoltaic array comprising a plurality of photovoltaic cells connected to one another and a pair of output terminals that are electrically coupled to the terminals of the battery.

In yet another version, a multifunctional panel comprises an exterior surface that is weather resistant, an interior surface that opposes the exterior surface, and an insulative body between the interior and exterior surfaces. A first sensor is provided to measure an interior condition in the interior of the building and generate an interior-condition signal, and a second sensor to measure an exterior condition in the exterior of the building and generate an exterior-condition signal. A switch is used to a turn a device on or off in response to the interior-condition signal, exterior-condition signal, or both.

A kit of multifunctional panels for a building, the kit comprising a sensor panel comprising: (i) an exterior surface, an interior surface, and an insulative body between the interior and exterior surfaces; (ii) a sensor to measure an interior condition of the building or an exterior condition of the building and generate a sensor signal; and (iii) a signal coupler to transmit the sensor signal to other panels, receive an input signal from another panel, or pass power to power a device in or about the insulative body. The kit also includes a controller panel comprising an exterior surface, an interior surface, and an insulative body between the interior and exterior surfaces, and a controller to receive a signal from the signal coupler to control a device in or about the insulative body.

A modular building comprises a shed comprising a framework of spaced apart columns that are linked to one another by overhead roof trusses, and a clerestory roof comprising a plurality of roof panels, wherein at least some of the roof panels are transparent to light. A multifunctional panel is on the shed or roof of the modular building.

### DRAWINGS

These features, aspects, and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIG. 1A is a perspective exploded view of an embodiment of a multifunctional panel for a modular building;

FIG. 1B is a partial sectional side view of two multifunctional panels having side splines that are coupled together, and showing the male and female electrical couplers of the two panels that can be plugged into one another;

FIG. 1C is a detailed partial sectional side view of a portion C of the panel of FIG. 1B;

FIG. 1D is a schematic sectional side view of a panel showing a differential signal generator connected to the sensors and the signal couplers, and an internet device;

FIG. 2 is a perspective exploded partial sectional view of another embodiment of a multifunctional panel having a frame;

FIG. 3 is a perspective partial sectional view of an embodiment of a multifunctional panel comprising photovoltaic cells and batteries;

FIG. 4A-C are electrical block diagrams showing the circuit connections to transfer electrical power generated by the photovoltaic cells to a battery, grid or lights, respectively;

FIG. 5 is a perspective exploded view of a section of a frame of a modular building comprising a tilted roof having multifunction panels comprising photovoltaic cells;

FIG. 6 is a side perspective view of a frame of a modular building comprising a shed, and titled roof, over a concrete grade beam foundation;

FIG. 7 is a schematic perspective view of the frame of an embodiment of a modular building having a shed with a tilted roof that forms a clerestory and a side expansion module; and

FIG. 8 is a perspective view of an embodiment of a modular building having a shed, clerestory, two opposing expansion modules, and multifunctional and sensor panels.

### DESCRIPTION

Embodiments of the present invention relate to a smart or multifunctional panel 20 for any building or building structure, and which can be used to perform any one or more of a variety of functions to increase the energy efficiency of the building or to facilitate its operation or use. The multifunctional panel 20 can also form the exterior skin of the building, such as for the roof or external sidewall of the building. The panel 20 can further provide the ability to control and automate building management functions that enhance the interior environment of the building. The multifunctional panel 20 can also be used to provide an energy-efficient, energy-neutral, or even an energy-positive building. The panel 20 can also be used to fabricate a “smart” modular building which is self-regulating or adaptive to different ambient environments or which can be tailored to specific climate environments or needs of its users. A smart building made using such panels 20 can adapt to different lighting, thermal management, humidity and other ambient conditions, which would otherwise require a custom on-site fabricated design for each site, environment, or specific user needs. The effective use of the panels 20 in a building can make the activities of the inhabitants more effective as human behavior and user equipment can be programmed into the electronics of the panel to respond better to certain ambient conditions which can be optimized by the panels without active management or action by the users. The multifunctional panels 20 also make building solutions less expensive to operate in a large variety of environments because they can greatly reduce the requirements for off-site generated fuel and can be adapted to different architectural applications.

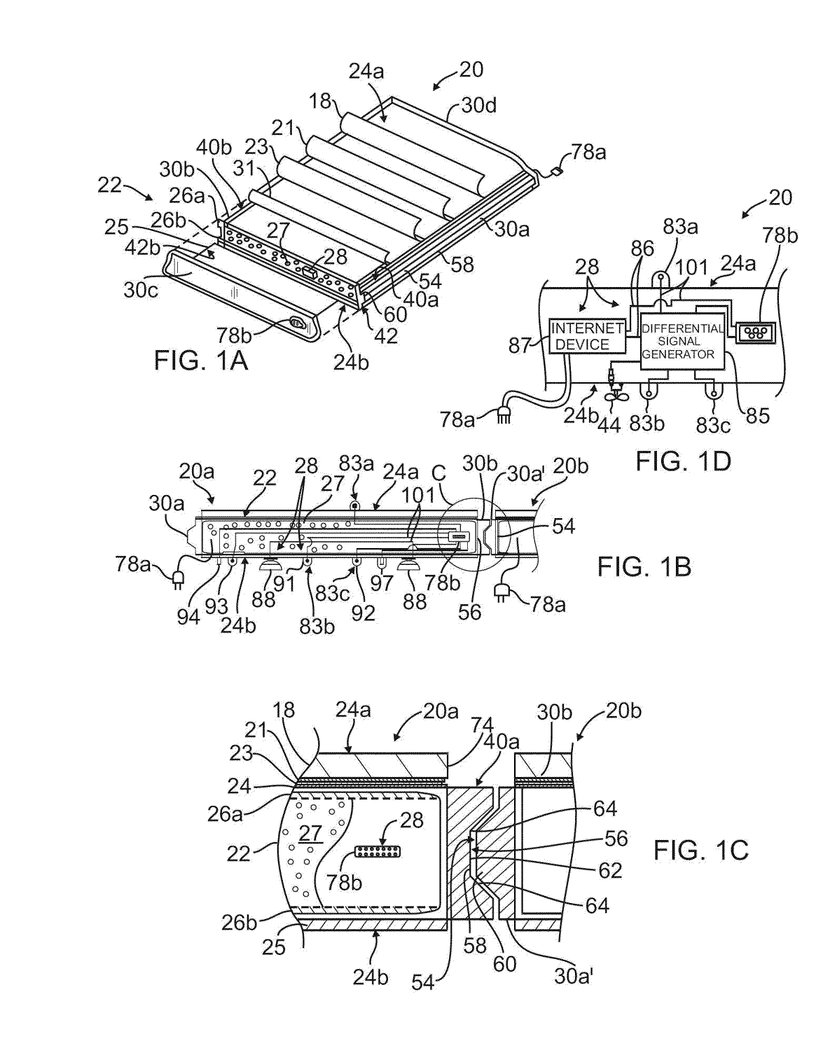

An exemplary embodiment of a multifunctional panel 20 is shown in FIGS. 1A to 1D. The multifunctional panel 20 comprises an insulative body 22, an exterior surface 24a, and an interior surface 24b that opposes the exterior surface, i.e., it is on the other side of the exterior surface. Either of the insulative body 22, exterior surface 24a, or interior surface 24b, can be made from a single material or a number of different materials in the form of sheets or layers to form the desired structure. While exemplary illustrative embodiments of the structure of different multifunctional panel 20 are described herein, it should be understood that the panel 20 can be made from a variety of different solid or molded materials, sheets or layers; thus, the scope of the present invention should not be limited to the illustrative embodiments described herein. The exterior and interior surfaces 24a,b, respectively, are separated by a distance to form an enclosed volume which contains the insulative body 22. In one version, the distance between exterior surface 24a and interior surfaces 24b comprises a distance of from about 5 to about 20 cm. However other sizes are possible depending on the application of the panel 20.

The multifunctional panel 20 can also be joined to other panels with end fittings or couplings to present a continuous weather resistant exterior surface and a fungible, smooth, interior finish surface. In one version, the exterior surface 24a comprises a weather resistant surface 18, by which it is meant that the surface 24a is waterproof to provide a moisture and rain barrier. The weather resistant surface 18 can also be a weather impact surface that protects the panel 20 and the interior of the building from impact damage—for example, damage caused by rain, ultraviolet solar damage, and more significant hazards such as hailstones, flying debris, snow, etc. It also serves as a weatherproof shield which greatly reduces passage of moisture to a waterproof membrane 21 that ultimately protects against moisture entering into the building structure. Suitable weather impact surfaces 18 include wood, composite recycled materials, metal sheets (such as a flat, ribbed or corrugated metal sheet), impact resistant polymer, or any other suitable type of roofing or exterior wall material that can accept long-term exposure to natural elements without significant decay.

In the version shown, the exterior surface 24a includes a waterproof membrane 21 that extends across the upper surface of the panel 20. The waterproof membrane 21 is provided to waterproof the underlying structure of the multifunctional panel 20. The waterproof membrane 21 resists water passage and is suitable for continuously wet environments as well as locations that experience dry and wet weather cycles. A building or structure is waterproofed to protect contents underneath or within as well as protecting structural integrity. Further, the entry of water into the interior of the panel can affect any devices in the panel, and it is desirable to protect from electrical shorting caused by water. For example, a suitable waterproof membrane 21 includes one or more layers of membranes made from materials such as bitumen, silicate, PVC, and HDPE. The waterproof membrane 21 acts as a barrier between exterior water and the building structure, preventing the passage of water.

The exterior surface 24a can also be, or have adjacent to it, a radiant barrier sheet 23 to reduce undesired radiant wave energy transfer from the exterior to the interior and thus, reduce building heating and cooling energy usage. The radiant barrier sheet 23 can also include a gap to serve as an air barrier that allows ventilation between the exterior surface and the waterproof membrane. This gap allows for the passage of air and the shedding of water that penetrates the weather impact surface 18. The radiant barrier sheet 23 reduces air-conditioning cooling loads in warm or hot climates. The radiant barrier sheet 23 can be placed adjacent to the waterproof membrane or lower down in the structure of the body 22. The radiant barrier sheet 23 comprises a thin sheet of a highly reflective material. The radiant barrier sheet 23 can also be a coating of a highly reflective material applied to one or both sides of a sheet such as paper, plastic, plywood, cardboard or air infiltration barrier material. A suitable radiant barrier material comprises aluminum, such as a sheet of aluminum. The radiant barrier sheet 23 has a high reflectivity or reflectance (e.g., a reflectivity of at least 0.9 or 90%). Reflectivity is determined as a number between 0 and 1 or a percentage between 0 and 100 of the amount of radiant heat reflected by the material. A material with a high reflectivity also has a low emissivity of usually 0.1 or less. An air gap is marinated adjacent to the reflective surfaces of the radiant barrier sheet to provide an open air space to allow reflection of the radiant energy and air circulation to remove the radiant energy from the panel surface. This gap also serves to reduce the collection of moisture on the radiant barrier sheet 23 and the waterproof membrane 21. In summer, the radiant barrier sheet 23 operates by reflecting heat back towards the external environment from the roof or wall to reduce the amount of heat that moves through the panel 20 and into the building. In winter, the radiant barrier sheet 23 reduces heat losses through the ceiling or walls of the building in the winter.

Optionally, building paper 31 can be placed, for example, between the waterproof membrane 21 and the radiant barrier sheet 23 as shown in the version of FIG. 1A. The building paper 31 serves as a secondary moisture-resistant and impermeable covering. Typically, building paper 31 is an asphalt-impregnated paper that comes in different weights. For example, building paper 31 comprising 15-lb paper is used for most roofing and moisture-sealing wall applications. Building paper 31 also includes felt paper, tarpaper, roofing paper, or roofing underlayment. Building paper 31 resists air and water getting into the structure but allows moisture to diffuse through it through fine pores in the paper that are sufficiently small to prevent penetration of water through the surface of the paper.

In one version, the interior surface 24b is a surface of an interior board 25. In one example, the interior board 25 comprises a fungible composition panel that extends across the entire lower surface of the panel 20. The interior board 25 is freely exchangeable or replaceable, in whole or in part, for another sheet of a similar nature or kind. The interior board 25 forms the exposed interior surface of the panel 20. The interior board 25 can have color or texture that provides an aesthetic interior ceiling or wall surface of the modular building 100. The interior board 25 can also be useful to hide electrical connections within the roof panel 20. In still another version, the interior board 25 comprises a coating made of a material that absorbs sound, provides additional thermal insulation, and/or is electrically insulating. The interior board 25 may also be separated from the exterior surface of the roof panel 20 by a distance of from about 5 to 20 cm to provide acoustic and thermal insulation between the interior and the exterior surfaces of the roof panel 20. When this sheet is used, the interior board 25 forms the interior facing surface 24b.

The insulative body 22 serves as a structural insulated panel to provide both mechanical or structural support and thermal insulation. In one version, the insulative body 22 comprises first and second structural boards 26a,b that are aligned to one another, as shown in FIG. 1A. The structural boards 26a,b can be oriented strand board, plywood, pressure-treated plywood, cementitious panels, steel, fiber-reinforced plastic, magnesium oxide or other sufficiently structurally sound materials. In one version, this gap or volume between the first and second structural boards 26a,b is filled with an insulating layer 27, as shown in FIG. 1A In one version, the insulating layer 27 serves as a support for, and provides rigid separation between, the structural boards 26a,b. The insulating layer 27 can comprise a material having a selected resistance to heat flow (which is termed an R-value) of greater than about 3.5 per 2.5 centimeters to provide some thermal insulation between the first and second boards 26a,b. The insulating layer 27 can be a foam such as expanded polystyrene foam, extruded polystyrene foam or polyurethane foam, soy or other organic bio-based materials as well as conventional fibrous or cotton insulation materials. The insulating layer 27 of the body 22 can be made using conventional construction techniques, including foam injection process in which the foam bonds directly to the structural boards 26a,b, providing a high bond strength.

In addition, the insulative body 22 can contain devices 28, such as energy storage devices 81, data and power connection devices 78, fans 44, one or more sensors 83a-c, lights 88, and other such devices, as for example, shown in FIGS. 1A-1C and 3. In one version, the insulative body 22 of the panel 20 can also have energy storage devices 81 that store energy in the panel 20. For example, the energy storage devices 81 can be a set of batteries 82. Each battery 82 comprises a rechargeable or storage electrochemical cell, typically comprising a group of two or more secondary cells which are capable of an electrochemical reaction that releases energy and is readily reversible. The rechargeable electrochemical cells accumulate electrical charge using cell chemistries such as lead and sulfuric acid, rechargeable alkaline battery (alkaline), nickel cadmium (NiCd), nickel metal hydride (NiMH), lithium ion (Li-ion), and lithium ion polymer (Li-ion polymer). For example, the batteries 82 can be charged by the electrical energy generated by a photovoltaic array, windmill-generated electrical power, or mains power from an electrical grid 80.

In the version shown in FIG. 3, the batteries 82 comprises a battery sheet 89 extending across a lower surface of the panel 20—for example, between the side splines 30a-d. The battery sheet comprises a sheet of a plurality of batteries 82 having terminals 99 which are interconnected to one another or other devices 28 via electrical cables 101. The battery sheet 89 can be sized to have a thickness of less than 20 mm, for example, or even less than 10 mm or even about 2 mm, and cover an area of the entire surface of the panel 20. An insulating material 27 or other filler can be used to fill the body 22 of the panel 20 to fill spaces between the batteries to provide thermal or electrical insulation.

The panel 20 can also have structural reinforcements around the body 22 of the panel. In one version, a pair of first and second side splines 30a, 30b, are provided at the edges of the body 22 to structurally bridge the gap between the first and second structural boards 26a,b. The splines 30a, 30b also seal off the insulating layer 27 from the external environment to provide a weather- and water-proof seal that reduces environmental or moisture degradation of the material or devices 28 in the insulative body 22. Further, the splines 30a, 30b can be shaped to allow interconnection of one panel 20 to another or to connect devices 28 in the building to the panel 20. The splines 30a, 30b each form a longitudinal segment having a length sufficiently long to extend across substantially the entire length of the panel 20. The splines 30a, 30b can have upper surfaces 40a, 40b that face the exterior of the building and lower surfaces 42a, 42b that face the interior.

In a further version, portions of the panels 20 such as the splines 30a, 30b, can have matching mechanical coupling elements that serve as interconnect features to join a number of panels to one another as shown in FIGS. 1B and 1C. For example, in the version shown, the outside sidewall of the first side spline 30a comprises a tongue 54 that is adapted to mate with, or fit into, a corresponding groove 56 of the outside sidewall of the second side spline 30b of the current panel 20. Referring to FIG. 1C, the tongue 54 comprises an outwardly extending ridge 58 having rounded corners 60, and the corresponding groove 56 comprises a longitudinal slot 62 having rounded edges 64. Two panels 20a,b can be coupled together by fitting the tongue 54 of the first side spline 30a into a corresponding groove 56 of the second side spline 30b. While a tongue and groove design is used to illustrate an exemplary version of an interconnect feature, it should be understood that other interconnecting or coupling elements can also be used as would be apparent to those of ordinary skill in the art. For example, the first side spline 30a can have an upper projecting ledge that slides over a lower projecting ledge of the second side spline 30b (not shown). In another version, the first side spline 30a can have a number of outwardly projecting and spaced apart balls that fit into correspondingly shaped apertures formed in the right-side spline 30b. In still another version, the first side spline 30a can have a “J” shaped upper flange that fit into correspondingly inverse “J” shaped lower flange formed in the second side spline 30b.

Optionally, the front and back ends of the body 22 of the panel 20 can be capped by third and fourth side splines 30c, 30d (which can be also called end or capping splines) to seal off the material or air in the body 22 from the external environment. The side splines 30c, 30d also enable connection of the panel ends to other panels or building components. The side splines 30c, 30d are fastened perpendicular to the side splines 30a, 30b, and can also include corner splines. In the version shown, the side splines 30c, 30d each comprise a flat beam without projecting coupling sections. However, the side splines 30c, 30d can have outwardly projecting coupling sections or other structures as would be apparent to those of ordinary skill in the art to allow coupling to other panels or to a frame of a building.

In one version, the multifunctional panel 20 with side splines 30a-d is sufficiently rigid and mechanically strong to serve as a structural roof member or even replace ceiling joists of a modular building. Also, any of the side splines 30a-d can be made by extruding a suitable metal. For example, the side splines 30a-d can be made by extruding aluminum or steel using conventional methods. Other materials, such as composite or polymer materials, can also be used as would be apparent to those of ordinary skill in the art.

The multifunctional panel 20 further includes one or more signal couplers 78a,b that serve as input and output terminals to transmit an electrical signal or electrical power. For example, the signal couplers 78a,b can transmit a sensor signal to other multifunctional panels 20′, receive an input signal from another multifunctional panel 20′, or pass power to power a device 28 in or about the insulative body 22 of the panel. The signal couplers 78a,b can also send output signals to other panels 20 or devices 28, receive input signals from other panels 20 or devices 28, transmitting or receiving a signal to or from a controller 90, form connections to and from data cables 86, or pass a power signal to power a device 28 anywhere in the building. The electrical signals transmitted by the signal couplers 78a,b can be electrical signals, such as analog signals or data signals. The signal couplers 78a,b can, for example, receive a signal from a sensor, photovoltaic cell, battery, heater, cooler, electrical grid, etc. and then transmit the signal to another device 28 in the building to control operation of the building. In this manner, the signal couplers 78a,b allow different panels 20a,b to communicate to one another and to the controller 90, thereby serving as “smart” panels that can communicate information, transmit sensor data, or even receive signals to operate a device 28 located within the panel 20 or adjacent to the panel 20. In one version, the signal couplers 78a,b include an electrical male plug (such as that shown by 78a) and a female socket (such as that shown by 78b) to receive the plug. For example, a suitable plug and socket system can be a multi-pin connector, such as an RS-232 plug and/or socket, a DIN plug/socket, a USB plug or socket, or other types of plugs and sockets. Each set of signal couplers 78a,b comprises pins to receive and transmit signals to signal couplers in other panels 20 or to the controller. These electrical signals control operation of the building and can include electrical power, sensor signals, or operational instructions from a controller. While a wired version of the signal couplers 78a,b is shown, the signal coupler can also be a wireless version, e.g., a wireless modem card or infrared signal transmitter and receiver.

In the version shown in FIG. 1A, a pair of signal couplers 78a,b are mounted in the side splines 30c, 30d, respectively, of the panel 20 to connect the panel 20 to other panels or to external systems. The signal coupler 78a serves as an input terminal and can include a multi-pin connector plug that mates with a matching output terminal comprising a multi-pin connector socket of the signal coupler 78b. The multi-pin connectors comprise connection pins that are capable of transmitting electrical power as well as data for other systems such as a sensor signal from an integrated sensor, electrical power from a photovoltaic cell array or battery, or even mains electrical power. The multi-pin connector's data pins may also be used to input data to a controller within the panel 20 or a controller 90. The signal couplers 78a,b can also be integrated into a multi-pin connector system. The multi-pin connector can include connection pins that are capable of outputting electrical power as well as data for other systems such as output from integrated lights, sensors, mains power, and batteries, as explained below. The multi-pin connector's data pins may also be used to input data to a controller within the panel 20 or outside and in the building structure.

The signal coupler 78a,b can also be of other types. For example, the signal couplers 78a,b can be radiofrequency signal couplers such as an RF transmitter and receiver. The signal couplers 78a,b can also be incorporated into an Internet device 87 and thus have a unique IP address. The radiofrequency signal coupler receives and transmits signals to other such devices within other panels or to a radiofrequency signal coupler mounted in electrical communication with the controller. Advantageously, only a single radiofrequency signal coupler is needed per panel as the device can function both to receive signals and transmit signals. In addition, the radio frequency signal coupler does need electrical wires to communicate with other devices or to receive or transmit signals. This facilitates installation of the “wireless” panels in the modular building.

Instead of, or in addition to, the signal couplers 78a,b, the panel 20 can also include a switch 96 to a turn a device 28 on or off in response to the interior sensor signal, exterior sensor signal, or both. The switch 96 can connect an electrical power source, such as the energy storage device or electrical power from the main electrical grid, to a device 28 such as a fan 44, lights 88, heater, cooler, air-conditioning unit, vent, or many other devices, to operate the device 28 in relation to the signal received from one or more sensors 83a-c. For example, the switch 96 can turn on, or turn off, a device 28 such as a fan 44, air conditioner, or heater, or open a vent in the building in response to a signal from a temperature sensor which indicates that the building is excessively hot or too cold. As another example, the switch 96 can generate a switch signal to operate an external device 28 in the same or another panel 20.

Referring to FIG. 1B, various devices 28 which are useful in the building can be attached directly to a panel 20 and located abutting or adjacent to the panel or positioned in other areas of the building but with an electrical connection to the panel 20. For example, a device 28—such as a light 88—can be attached to the interior surface 24b of the panel 20. In one version, the light 88 is directly electrically coupled to the output terminals of an array of photovoltaic cells or to batteries, as explained below. When the light 88 comprises a direct current (DC) powered source, advantageously, the light can be powered directly by the DC voltage output of the solar cells without inverting or rectifying this voltage. This significantly improves the energy efficiency of the light and solar cells. Other direct current devices 28, such as fans 44 or motors or hydraulics to operate vents and skylights, can also be used instead. Any of the DC devices 28 have the benefit of not requiring conversion of the DC voltage generated by the solar cells to alternating current (AC), thereby avoiding the inefficiency of DC to AC conversions, the cost of rectifiers, and less heat generation.

The multifunctional panel 20 can also have one or more sensors 83a-c that function with the signal couplers 78a,b to form a close control loop with a controller or with other panels as shown in FIGS. 1B and 1C. The sensors 83a,b can be mounted on the exterior surface 24a or the interior surface 24b of the panel 20 or both sides. For example, one or more exterior sensors 83a can be used to measure an exterior condition of the exterior environment from the exterior surface 24a of the panel 20 and generate an exterior-condition signal, and one or more interior sensors 83b and/or 83c can be used to measure an interior condition of the interior of the modular building from the interior-side of the panel 20 and generate an interior-condition signal. The interior and exterior condition signals can be evaluated by a device inside or outside the panel 20 to operate another device in the building or attached to a panel 20. While two sensors are shown, it should be understood that a single sensor 83 that can measure both the interior and exterior conditions can also be shown.

A differential signal generator 85 can be used to receive the interior-condition and exterior-condition signals from the sensors 83a-c to evaluate the signals. In this version, the differential signal generator 85 comprises electronic circuitry to generate a sensor signal that is a differential signal which is calculated in response to the differential between the measured interior and exterior conditions. A single sensor 83a having a built-in differential signal generator can also measure both the interior and the exterior conditions and generate a sensor signal in response to the differential between the measured interior and exterior conditions. The differential or direct sensor signals convey information about the interior or exterior building environment via differential or other measurements from the interior and exterior and transmit the information via the signal couplers 78a,b to other panels 20 or to the controller 90 which, in turn, evaluate the sensor signal and regulate operation of the building in response to the sensor signal to provide a self-regulating automated modular building. The sensors 83a-c can be, for example, a temperature sensor, humidity sensor, light sensor, air quality sensor, sound sensor, electrical sensor (such as a voltage or current detector), and other types of sensors. Thus, the sensors 83a-c enhance operation of the building by providing sensor signals for the controller, another panel 20, or another building device, such as a light, fan heating or cooling system, or even motorized shutters. The sensors 83a-c can also activate a phase change material within the insulative body of the panel 20.

In one version, the sensors 83a,b include a temperature sensor 91 that is used to measure the ambient temperature in the interior of the building, a room of the building, and/or an ambient exterior temperature outside the building. The temperature sensor 91 generates a temperature signal in relation to the measured interior and exterior ambient temperatures, this signal being used to adjust the heating and cooling systems to control the temperature in the building. Suitable temperature sensors 91 include, for example, a thermocouple, resistance temperature detector, or bimetallic sensor. The temperature sensor 91 measures the temperature adjacent to the panel or at an interior section of the building and transmits the temperature measurement via the signal couplers 78a,b to other panels 20, to the controller 90, or to devices 28. The temperature signal is then used to control or regulate the temperature within the building, e.g., by increasing or decreasing the building heater power level, operating ceiling fans 44, opening motorized windows or shutters, or opening skylights.

In another version, the sensors 83a,b include a light sensor 92 that is capable of detecting and measuring the ambient light intensity in the interior of the modular building 100 and generating an ambient light signal in relation to this measurement. The signal couplers 78a,b transmit the ambient light intensity signal provided by the light sensor 92 to other multifunctional panels or to the controller. The light sensor 92 can be a photovoltaic sensor or other light-sensitive sensors. The ambient light signal of the light sensor 92 is used to turn on or off or to diminish different lights 88 to increase or decrease the intensity of light within the building or even open motorized shades or shutters in windows, thereby increasing or decreasing interior light on a self-regulating, as-needed basis to the interior of a building. For example, as cloud cover reduces available natural light below desired levels or the day darkens into evening, the diminishing light signal from the light 92 sensor can be used to increase power supplied to lights in the interior of the building to open or close shades, etc. The light sensor 92 can also be mounted on the exterior surface 24a to measure the outside light conditions to control exterior lights. In one version, a first light sensor 92a is mounted on the interior surface 24b to measure an ambient light intensity of the interior of a building, and a second light sensor 92b is mounted on the exterior surface 24a to measure an ambient light intensity of the exterior of the building. The differential signal can be used to control the intensity of the lights in the building, or each of the interior and exterior light intensity signals can be used to set the light intensity inside or outside the building respectively.

In still another version, the sensors 83a,b include a humidity sensor 93 mounted on an interior surface 24b to measure a humidity level of the interior and/or exterior of the building and generate a humidity signal in proportion to the measured humidity levels. The signal couplers 78a,b transmit the humidity signal to other multifunctional panels or to the controller. For example, a suitable humidity sensor 93 can be a relative humidity sensor.

In yet another version, the sensors 83a,b include an air-quality sensor 94 mounted on the interior surface 24b to measure an air quality of the interior of the building 100 and/or mounted on the exterior surface 24a to measure an air quality of the exterior of the building 100. The air-quality sensor 94 continuously monitors the air quality and generates an air-quality signal that is sent via the signal couplers 78a,b to other panels or a controller. The air-quality signal provides energy savings through demand-based control of outside air intake, improves and optimizes the air quality of the facility, and can even identify potential air quality problems in the early stages. A suitable air-quality sensor 94 comprises an oxidizing element that, when exposed to gases in an environment, changes in resistance depending on the chemical composition of the gases and provides an output air-quality signal that corresponds to the combined concentration of a number of contaminant gases typically found in indoor environments. This provides a much more accurate representation of the actual air quality than, for example, a CO or CO₂ sensor which senses only CO or CO₂ and not other contaminant gases. An exemplary version of a suitable air-quality sensor 94 comprises a BAPI Room Mount Air Quality Sensor™ fabricated by Building Automation Products, Inc., Wisconsin. The output air-quality signal generated by the air-quality sensor 94 is transmitted to the controller which evaluates the signal and generates an output signal to control the amount of outside air introduced by a ventilation plant into the building. By controlling ventilation, the system reduces energy consumption by eliminating the introduction of excess outside air into the building during periods of little or no occupancy.

In still another version, the sensors 83a,b include a sound sensor 97 mounted on the exterior surface 24a or interior surface 24b to measure the ambient sound levels outside or inside the building. The sound sensor 97 can measure decibel levels. The sound sensor 97 can be a conventional microphone. The signal from the sound sensor 97 can be used to lower sound absorbing curtains if the ambient noise in the building is too high, close windows if the exterior noise levels are too high, and other such functions.

The panel 20a can also have an internet device 87 with an internet protocol address, as shown in FIG. 1D. The internet device 87 can be, for example, an integrated circuit chip with attached memory, a programmable logic chip, a wired or wireless modem, or a router. The Internet Protocol (IP) is a protocol used for communicating data across a packet-switched internetwork using the Internet Protocol Suite, also referred to as TCP/IP. IP is the primary protocol in the Internet Layer of the Internet Protocol Suite and has the task of delivering distinguished protocol datagrams (packets) from the source host to the destination host solely based on their addresses. For this purpose, the Internet Protocol defines addressing methods and structures for datagram encapsulation. Current versions include Internet Protocol Version 4 (IPv4) and Internet Protocol Version 6 (IPv6). An Internet Protocol (IP) address is a numerical identification and logical address that is assigned to a device participating in a computer network utilizing the Internet Protocol for communication between its nodes. Although IP addresses are stored as binary numbers, they are usually displayed in human-readable notations, such as 208.77.188.166 (for IPv4) and 2001:db8:0:1234:0:567:1:1 (for IPv6). The IP address includes a unique name for the device, an address indicating where it is, and a route indicating how to get there. TCP/IP defines an IP address as a 32-bit or 128-bit number. The Internet Protocol also has the task of routing data packets between networks, and IP addresses specify the locations of the source and destination nodes in the topology of the routing system. A data cable 86 is used to enable communications amongst the devices within the insulative body, such as the sensors 83 and internet device 87, and it can also be connected to the signal couplers 78a,b to network with other panels 20b as well as the controller 90.

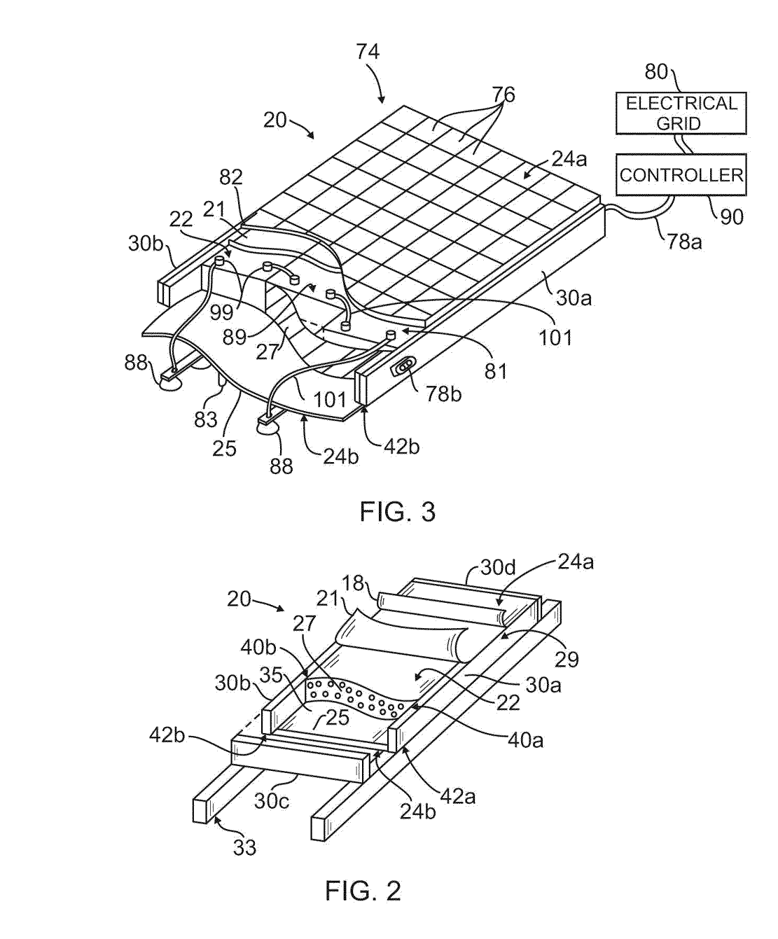

Another version of the multifunctional panel 20 comprises an insulative body 22 that has more rigidity to serve, for example, as structural roof member or even replace ceiling joists of a modular building. In the version shown in FIG. 2, the structural panel comprises a frame 29 comprising a pair of side splines 30a, 30b that oppose one another. The side splines 30a, 30b have upper surfaces 40a, 40b and lower surfaces 42a, 42b, are parallel to one another and span across the entire length of the panel 20 to define the left and right edges of the panel 20. The side splines 30a, 30b are connected at their ends by the side splines 30c, 30d to form an enclosed interior volume 35. Typically, the side splines 30a-d are configured to define a rectangular interior volume 35, such as the parallelogram or cube. The interlocking surfaces of the panels formed at the junctions of the side splines 30a-d in the embodiment shown can be joined by conventional means, such as welding, nuts and bolts, or brazing. The side splines 30a-d can also be braced with right-angled supports (not shown) at their corners for additional support. The geometry of the planar roof panel 20 facilitates welding or fastening the panel 20 in-place to a roof section 33. For example, a set of fasteners 37 comprising screws, nails, or clips can be used to fasten the roof panel 20 to a roof joist 115 of a roof.

In this embodiment, side splines 30a-d are all shown as solid longitudinal beams; however, it should be understood that other structures equivalent to the longitudinal beams can also be used, such as a plurality of interconnected X-structures, multiple beams joined by vertical members, a honeycomb structure, or other structures as would be apparent to those of ordinary skill in the art. The side splines 30a-d can be fabricated from metals such as steel, stainless steel, or aluminum.

The panel 20 also has an exterior facing surface 24a formed of a layer, such as a waterproof membrane 21, and the interior surface 24a can be that of an interior board 25. The interior and exterior facing surfaces 24a,b extend between splines 30a-d to enclose interior volume 35. The interior volume can be empty space or can have an insulating layer 27 (as shown), or batteries 82 (not shown). The volume 35 serves as insulation, vapor and air barrier between the inside of the building and the external environment. In one version, rectangular interior volume 35 is filled with an insulating layer 27 such as a foam or fiber mat.

In yet another version, the multifunctional panel 20 comprises an exterior surface 24a having a photovoltaic array 74 comprising an array of photovoltaic cells 76, as shown in FIG. 3. Such a panel 20 can be mounted on the exterior of the building to generate electricity from incident solar energy. A modular building 100 fabricated with a plurality of such multifunctional panels 20 reduces the amount of energy required to operate the building or may even provide sufficient energy to the building so as not to require a connection to the electrical grid 80. In sunny climates, the building 100 can be outfitted with a sufficient number of multifunctional panels 20 to output enough electricity to power its own lights or other building or user utilities and equipment. The photovoltaic cells 76 can cover a waterproof membrane 21. The photovoltaic array 74 may also require structural framing (not shown) to affix it to the panel 20. The photovoltaic cells 76 convert solar energy into electrical energy by the photovoltaic effect. Assemblies of photovoltaic cells 76 connected to one another in a series and/or parallel arrangement are used to make a photovoltaic array 74. For example, a panel 20 can have a photovoltaic array 74 comprising from 10 to 200 cells or even from 15 to 50 cells. A signal coupler 78a can serve as an electrical output terminal to output the electricity generated by the photovoltaic cells 76.

In one version, the batteries 82 in the insulative body 22 of the panel 20 are electrically coupled to the output terminals of the photovoltaic cells 76. The batteries 82 comprise terminals 99 which are interconnected to one another, to the photovoltaic cells 76, and/or the signal couplers 78a,b via electrical cables 101. The cells 76 charge the batteries 82 during the day, and the electrical power of the charged batteries can be used to operate the light 88 at night. The batteries 82 can also be charged by the electrical energy generated by the photovoltaic array 74 or from other multifunctional panels and/or main power from the electrical grid 80 via a power connection in the signal coupler 78a.

In one version of the panel 20, the array of photovoltaic cells 76 and the batteries 82 are directly electrically coupled to the lights 88 and to the output terminals 78a of the panel 20. When the lights 88 comprise direct current or DC powered lights, they are powered directly by the DC voltage output of the cells 76 without inverting or rectifying this voltage to improve the energy efficiency of the light 88 and cells 76. For example, the electrical cables 101 can connect the positive and negative terminals 99 of the photovoltaic array or a battery sheet 89 to the lights 88.

The array of cells 76, batteries 82, sensors 83, differential signal generator 85, internet device 87, and signal couplers 78a,b can also be connected to a controller 90, such as an external controller located elsewhere in the building or an internal controller built into a particular panel 20. The controller 90 can include a central processing unit (CPU), such as an Intel Pentium or other integrated circuit, a memory such as random access memory (RAM) and storage memory such as an electronic flash memory or hard drive, and connectors for connecting input and output devices such as keyboards, mice and a display. The controller can also contain a software program comprising program code to receive electrical signals from any of the devices 28, including the signal couplers 78 a,b, sensor signals from the sensors 83a-c, power from photovoltaic cells 76 or the electrical mains, and control the signals returned to the devices 28. For example, the controller 90 can receive a signal from a light sensor 92 that indicates the ambient light levels in the building, and send an output signal to connect the lights 88 to a voltage source such as the batteries 82 or the electrical grid mains 80 depending on the external light conditions or power cost. The controller 90 can also serve as a central information source to contain data generated by the sensors or libraries of data, logic, programs, etc.

The controller 90 can also be linked to an off-site data storage and processing server to enable communication with other controllers as well to receive information external to the site but that may optimize operation of the smart system. This external information could include weather forecast information including projected temperature, wind, sun, humidity and other data for the controller 90 to anticipate required operation of the smart panels linked to the controller 90. For example, if the weather forecast anticipates a storm, the controller 90 can shut windows in the building before the storm hits the building.

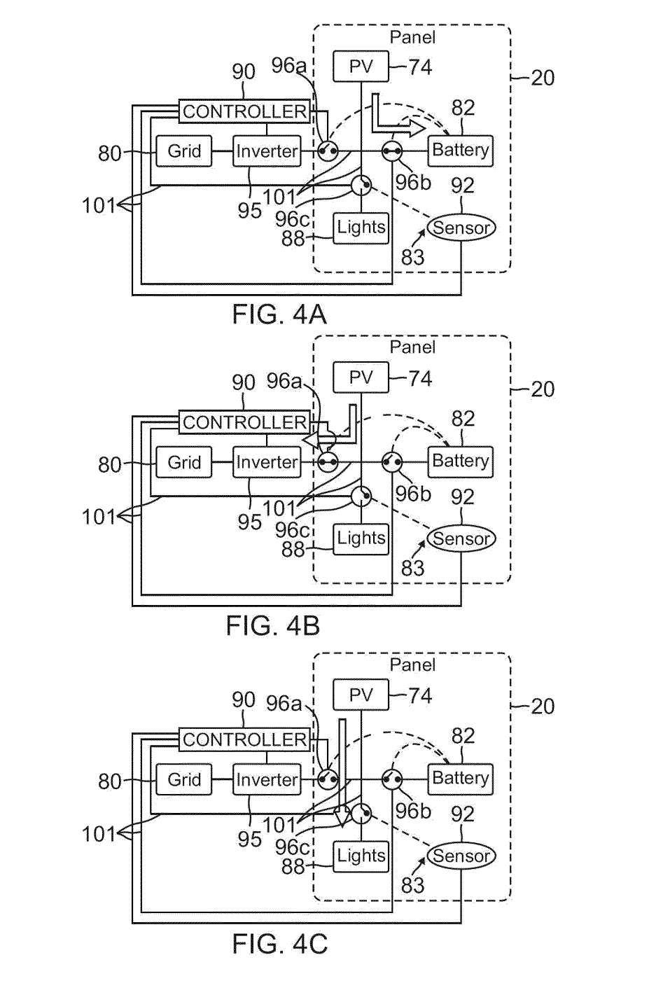

FIG. 4A-C are electrical block diagrams showing the circuit connections to transfer electrical power generated by the photovoltaic array 74 to an electrical grid 80, battery 82, or lights 88, respectively. These devices are interconnected by the electrical cables 101 and switches 96a-c are provided to control the flow of electrical power. An inverter 95 is provided to convert the DC voltage provided by the photovoltaic array 74 into an AC voltage suitable for passing to the electrical grid 80 or powering AC devices in the building. FIG. 4A shows the electrical connections made when the switch 96b is closed and the current from the photovoltaic array 74 is used to charge the battery 82. In this mode, the switches 96a,c are left open while the battery is charging. FIG. 4B shows the electrical connections made when the switch 96a is closed and switches 96b,c are left open, causing the current from the photovoltaic array 74 to be passed through the inverter 95 and back to the electrical grid 80 to obtain an electrical power discount. This allows the grid-tied electrical system to feed excess electricity generated by the photovoltaic array 74 back to the local mains electrical grid. When insufficient electricity is generated or batteries 82 are not fully charged, electricity drawn from the mains grid 80 makes up for any short fall. FIG. 4C shows the electrical connections made when the switch 96c is closed and the current from the photovoltaic array 74 is used to power the lights 88 or other devices in the building. The switches 96a-c can be manually operated or operated using the signal from sensors 83 such as a light sensor 92.

Optionally, a controller 90 which serves as a central information resource can also be used to control the various switches 96a-c, inverter 95, sensors 83 such as the light sensor 92, and other devices. The controller 90 can be a separate device or can be integrated into the inverter 95 or other device. The controller 90 can also be built into one of the panels 20. For example, the switches 96a-c can be manually operated or operated using sensors 83 such as a light sensor 92, or using software code embedded in the controller 90. In this version, the controller 90 comprises software code to receive a input signal from a sensor 83, such as an interior building light or external light output signal from a light sensor 92, a humidity level signal from a humidity sensor, a temperature signal form a temperature sensor, or other. The controller 90 can also receive a signal from the photovoltaic array 74 indicating generation of electrical power (or not) or the battery 82 indicating a fully charged state or a depleted charge state. The software code in the controller 90 evaluates the input signal and generates an output signal to control the switches 96a-c to charge the battery 82 by closing the switch 96b and directing the output of the photovoltaic array 74 to the battery 82, or close the switch 96a to send excess power generated by the photovoltaic array 74 to the inverter 95 and back to the electrical grid 80, or close the switch 96c to direct DC power directly from the photovoltaic array 74 to the lights 88 or other devices in the building. In this manner, the circuitry associated with a panel 20 can operate the building in a manner that most efficiently utilizes the available solar energy resources or for other ambient conditions.

A kit of multifunctional panels can also be used for a single building. In one version, the kit comprises a sensor panel 20 comprising an insulative body 22 between an exterior surface 24a and interior surface 24b. An exterior sensor 83a is used to measure an exterior condition of the building 100 and an interior sensor 83b to measure an interior condition of the building 100, or a single sensor 83 can be used to measure both the interior and exterior conditions of the building 100. The sensor panel 20 also includes one or more signal couplers 78a,b to transmit the sensor signal generated by the sensors 83a,b to other panels 20′, receive an input signal from another panel 20′, or pass electrical power to power a device in or about the insulative body 22 of the panel 20. The signal coupler 78a,b can transmit any one of the interior or exterior sensor signals to other panels 20 or to the controller. The signal coupler 78a,b can also pass a switch signal from a switch 96a-c to an external device 28 in another panel 20. The same kit can also includes a controller panel 20′ comprising an exterior surface 24a, interior surface 24b, and an insulative body 22 therebetween and a controller 90 to receive a signal from the signal coupler 78a,b to control a device in or about the insulative body 22. Various other panels 20 can also form part of the kit. For example, the kit can include a panel 20 having only a pair of signal couplers 78a,b to transmit an electrical signal from one panel to another or to form a chain of panels to relay a signal from a sensor panel 20 to a controller panel 20′ or to an external controller 90.

Various other types of kits can also be designed for particular applications. For example, a kit of panels 20 for a hot environment or location can include a panel having a device such as an AC or DC powered fan 44, motorized vent, or motorized or hydraulic operable window for opening the panel 20 to allow hot air to escape from the building 100. Still other kits can include panels having devices such as heaters for use in buildings adapted to cold environments. Still further, a kit of panels can include panels comprising signal couplers 78a,b which are wireless to communicate signals from sensors 83 to a central controller 90 inside the building or at a distant location. The kit of multifunction panels 20 or individual panels 20 can be easily shipped and mounted on a roof or wall of a building 100 that is a modular building or kit building. The panels 20 and other structural components of the building are rapidly deployable and easily transportable, minimizing both on-site assembly time and resource consumption.

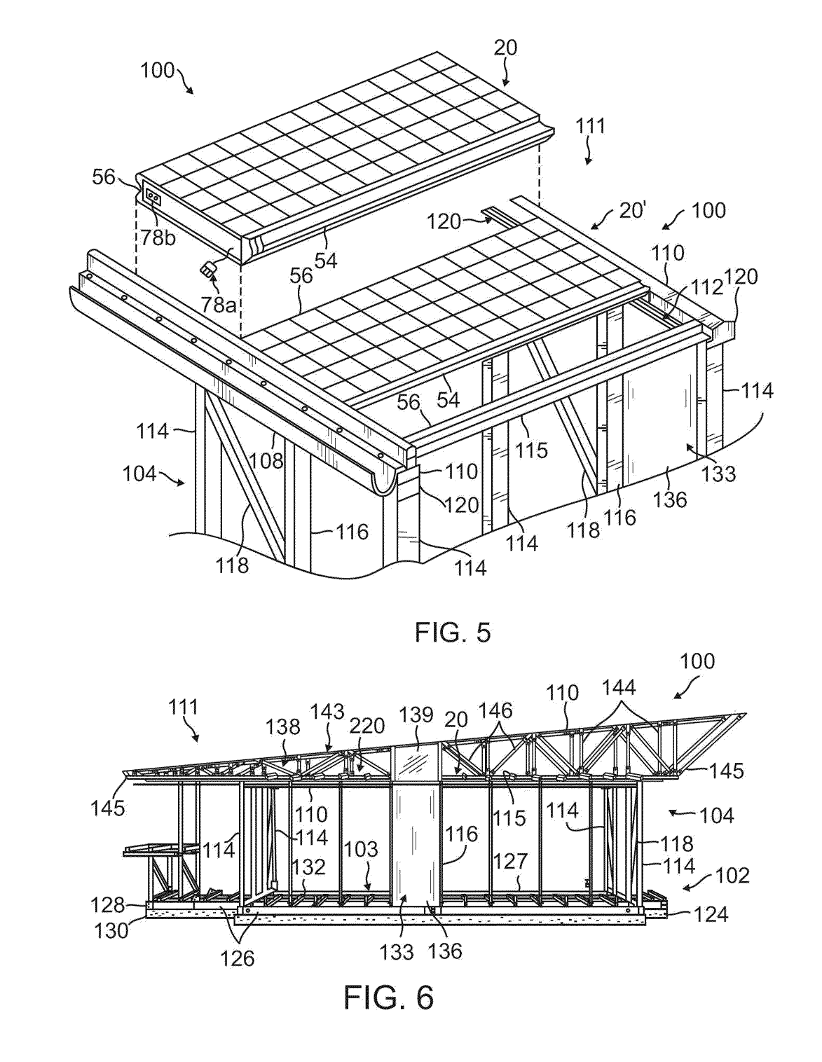

An exemplary and illustrative embodiment of a structural frame of a modular building 100 which can use one or more of the panels or a kit of panels, as shown in FIGS. 5-7. However, it should be understood that the illustrative embodiment of the building 100 herein is not intended to limit the scope of the invention, and the panels 20 and other structures according to the present invention can be used in other building designs as apparent to those of ordinary skill in the art.

In the version shown the building 100 comprises a support sled 102 with a shed 104 and optional side expansion modules 106. The sled 102 serves as a support and base for the shed 104 and can also be used to provide preassembled electrical connections for electrical services and mechanical services, such as ventilation, heating, cooling, and water plumbing. The shed 104 provides an enclosed housing structure that rests on the sled 102 which serves as the interior space of the modular building 100. The expansion modules 106 can be used to expand the interior space of the modular building 100 to provide extra space or to contain facilities such as restrooms, electrical power equipment, or other building service equipment. In the diagram shown, the sled 102, shed 104, and expansion modules 106 have rectangular structures; however, it should be understood that other shapes and structures (e.g., cylindrical or spherical structures) can also be used as would be apparent to those of ordinary skill in the art. Thus, the scope of the invention should not be limited to the illustrative embodiments described herein.

A roof 111 forms the ceiling of the shed 104 and optional expansion modules 106 and can be flat or triangular-shaped or have other shapes. In the version shown in FIG. 5, a plurality of multifunctional panels 20, 20′ comprising a photovoltaic array 74 are fitted together to form a rigid roof of the modular building 100. For example, the multifunctional panels 20, 20′ can be spaced apart to form a roof 111 that spans the width between the trusses 110. The trusses 110 are equipped with attachment surfaces 112 for fastening the roof panels. The multifunctional panels 20, 20′ can be fastened directly to each other and to the trusses 110 and/or fastened to roof joists 115 using conventional fastening means. Each multifunctional panel 20 is interlocking and has tongue 54 and groove 56, respectively, that mate with one another to snap-fit and interlock with one another (as previously described) to form a continuous rigid roof. The roof joists 115 span the length between trusses 110. The trusses 110 rest on and are anchored to the steel frame of the underlying shed 104 (or expansion module 106). A drainage channel 108 can be optionally mounted on an end of the roof 111. The roof 111 formed by the trusses 110, roof joists 115, and panels 20 provide a high-strength structure for situations such as storm or high-snow environments. The panelized roof 111 also allows for quick and easy building assembly on-site and provides a highly flexible and tailorable interior space.

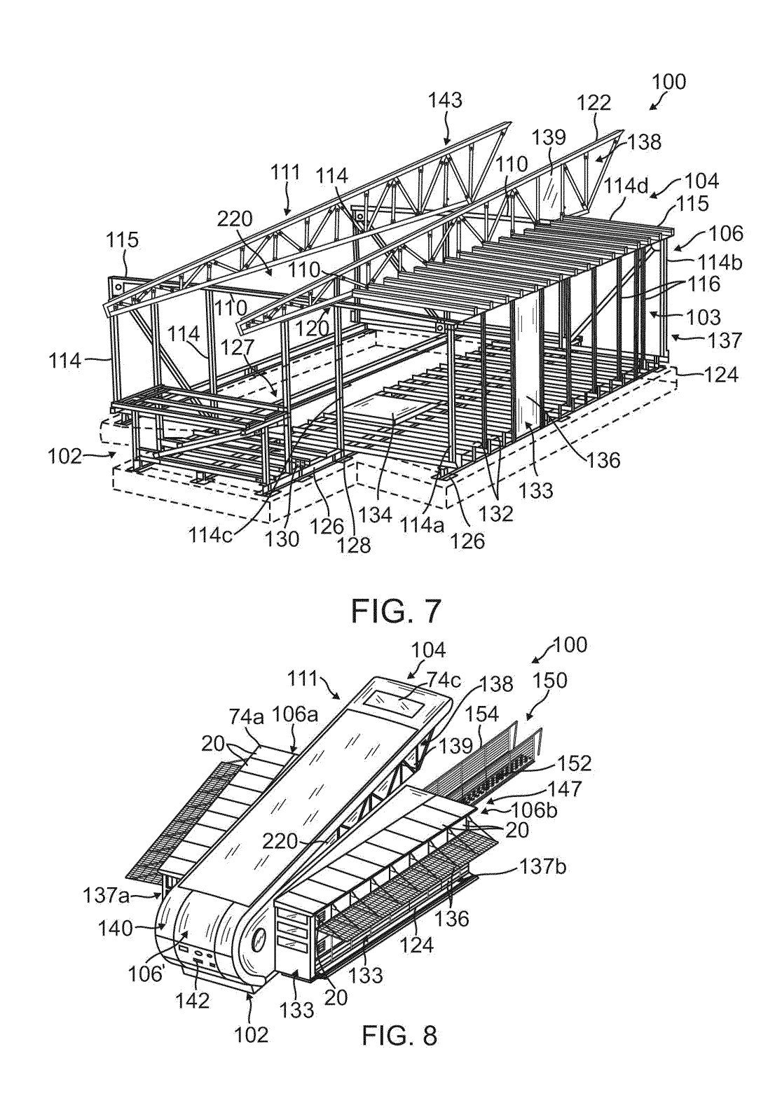

In one version, the building is supported by a sled 102, an exemplary version of which is shown in FIGS. 6 and 7. The sled 102 comprises a rectangular frame 103 composed of wide flange beams 126 that are spaced apart and rest on underlying concrete grade beams 124, leveling stands, and metal plates. The wide flange beams 126 are oriented in a rectangular configuration and are joined to one another by high-strength bolts 128. The sled 102 can be anchored into the concrete grade beams 124 and leveled using cast-in-place or post-poured, drilled, high-strength bolts 128 or the leveling stands and metal plates. The wide-flange beams 126 can even be equipped with custom mounting surface such as welded flat plates 130 that enable them to be mounted to the concrete grade beams 124. The concrete grade beams 124 can be oriented to provide a hollow region 127 underneath the sled 102 for placement of prefabricated electrical and ventilation system devices. The constructed sled 102 provides a preassembled structural platform with good structural integrity and pre-tested bolted and welded connections, allowing a flexible configuration of any overlying shed 104 or expansion module 106.

In another version, the sled 102 has a minimal number of connections to concrete footings, piles, or other site-intensive foundation elements which are sufficient to manage the dead load and lateral load associated with high winds or seismic forces. The connections to the ground allow resting of the load on the ground and holding the structure down in case of extreme wind or other uplifting force.

The sled 102 also has floor joists 132 that extend across the floor to provide structural rigidity. The floor joists 132 can comprise light gauge metal sections or beams. A raised floor is formed from floor panels 134 placed between the framework of the floor joists 132 to provide the necessary structural diaphragm for the base of the shed 104. As one example, the floor panels 134 can be made from structural metal decking. As another example, the floor panels 134 can be composed of concrete-filled metal pans that sit on pedestals so that the underlying cavity can house electrical and mechanical services. The floor panels 134 can also be rearranged to move outlets, ports, and air diffusers, providing the user with maximum flexibility. The under-floor distribution of mechanical services for the overlying shed 104 can include HVAC (heating, ventilation and cooling) tubes, electrical junction boxes, data cabling, and preassembled wiring. Locating electrical and mechanical services underneath the floor of the shed 104 provides an infrastructure for such services and can be tailored without extensive pre-wiring and ventilation planning for the overlying shed 104.

The shed 104 comprises a framework of spaced apart major and minor columns 114, 116, respectively, that each include beams and braces, such as steel beams. The major columns 114 are located at the corners of the shed 104 and attached to the underlying wide flange beams 126 of the sled 102, and the overlying roof trusses 1120, roof joists 115, and roof panels 20. Minor columns 116 are bolted to the floor joists 132 of the sled 102. In addition, diagonal columns 118 can also be used to brace the structure of the shed 104 and increase its lateral and shear strength. The columns 114, 116, 118 are linked to one another by overhead roof trusses 110 and joists 115, and can be connected by headers 120 (gussets) to provide vertical strength in support of the ceiling. In one version, all these members—namely the columns 114, 116, and 118, roof trusses 110, and other such structural members—are linked together with headers 120 and bolted together for gravity load and lateral strength to achieve predictable structural performance in a wide range of configurations and locations.

The walls 133 of the shed 104 and expansion module 106 can be formed by spacing apart the minor columns 116 a sufficient distance to accommodate wall panels 136 such as light-impermeable or light-permeable panes, such as windows, translucent screens, or even doors. Advantageously, positioning the minor columns 116 a predefined spacing distance provides a highly adaptable exterior sidewall 137 for the shed 104, so that each exterior sidewall 137 can be adapted to allow the transmission of light, serve as an opaque wall, or even provide a solar connection of the interior space of the shed 104 to other structures, such as an expansion module 106. The structure of the shed 104 also enables the two long exterior sidewalls 137a,b (as shown in FIG. 8) to be absent structural reinforcements which are conventionally needed to provide strength in seismic or storm locations, consequently enabling the shed 104 to have a variety of different external wall configurations.

Optionally, the modular building can also include a plurality of expansion modules 106, 106a,b designed to be attached to an open sidewall or end wall of the shed 104 to expand the usable enclosed space provided by the shed 104, as shown in FIGS. 7 and 8. Each expansion module 106, 106a,b comprises an external sidewall 137a,b, and they are linked to the shed 104 by the roof trusses 110 to define an open interior space encompassing the combined area of the expansion modules 106a,b and the shed 104. In the version shown, the expansion modules 106a,b each comprise major columns 114a-d that form the corners of its structural frame, at least two of the major columns 114a,b being external to the shed 104 and two other major columns 114c,d being in a sidewall of the shed 104. The expansion module 106 also has a sidewall 137, 137a,b with minor columns 116 that can be spaced apart as described in the minor columns 116 of the shed 104 to allow spaces for light-permeable panes, doors, or other structures. The expansion modules shown in FIG. 7 extend outward perpendicularly from the shed; however, alternate arrangements are possible, such as wedge-shaped side expansion modules, as shown in FIG. 8.

The building 100 can comprise other expansion modules 106′, such as a power pack module 140 as shown in FIG. 8. The power pack module 140 comprises electrical and mechanical systems suitable for the selected size of the building 100. For example, the power pack module 140 can include a bank of batteries 82 (not shown) with suitable electrical control and monitoring equipment such as the switches 96a-c, inverter 95, and controller 90 (which can be a charge controller) to receive and store electrical power from solar multifunctional panels 20 and distribute stored electrical power to electrical systems within the building 100, such as the lights 88 and ventilation system (not shown). An electrical generator 142 can also be provided in the power pack module 140 to supply additional power to the building 100 and its electrical systems. The power pack module 140 provides a convenient, transportable solution that is preconfigured to the interior volume of the modular building 100 that may include a shed 104 and suitable expansion modules 106.

The roof 111 of the modular building 100 can have variable heights and also provide optional and optimized clerestory natural lighting. As a result, the modular building 100 can be tailored to a wide range of interior environments while still providing a quick-to-deploy modular building 100 that is safe and long-lasting. In one version, the roof 111 comprises roof trusses 110 that are mounted in an angled position to form a tilted roof 111 enclosing a triangular volume. The tilted roof 111 can be equipped with light-permeable panes 139 that serve as clerestory windows along the triangular gap 138 between the roof plane 143 and the walls 133 and sidewalls 137 of the shed 104, as shown in FIGS. 6-8. The tilted roof 111 comprises a plurality of vertical struts 144 and diagonal struts 146 that allow for mounting of the light-permeable panes 139 in a clerestory configuration. In one embodiment, the tilted roof 111 is mounted to the major columns 114 of the shed 104 with hinges 145 that allow for the tilted roof 111 to be folded down to lie flat against the ceiling of the shed 104. The hinged tilted roof 111 allows for the roof of the modular building 100 to be flattened into a horizontal position during periods of high wind conditions, such as what might occur during transportation of the shed by truck to the building site. The ceiling 220 below the tilted roof can be an open ceiling (as shown) or can be an enclosed ceiling formed by the roof panels (not shown). The titled roof 111 provides a rigid framework which also allows easy expansion of the interior space provided by the shed 104 while providing good structural strength in high wind and high seismic applications.

The modular building 100 can also have multifunctional panels 20 located on the walls 133 or sidewalls 137 of the building 100. For example, the multifunctional panels 20 can be positioned on the upper section 147 of the sidewall 137b as shown in of FIG. 8. These panels 20 can be shaped and sized to fit into this space. Further, the panels 20 can have other shapes corresponding to other panels of the building and mounted in other lower positions as well.

The modular building 100 can be customized to include additional components. For example, a handicapped access ramp 150 comprising a rigid tilted surface 152 and hand rails 154 can be provided at an entrance to the shed 104. The access ramp 150 can be configured to allow passage of wheeled devices, such as wheelchairs and strollers, from ground level outside of the modular building 100 to the interior of the shed 104. As another example, a sun shade structure such as an awning 156 can be provided to filter or even block direct sunlight to some or all of the side panels of the modular building 100. The multifunctional panels 20 would enable these additional components to have access to power, data, and other technology directly from the panels. The roof panels 20 can also be supported on peripheral structures, such as the awning 156.

A modular building 100 according to the described embodiments is designed to be self-regulating and easily adaptive to different environments. The modular building 100 also controls lighting, thermal management, humidity, air-quality, acoustics, and other conditions in the building to (i) optimize these conditions for the occupants while increasing the efficiency of these systems to reduce external costs in electricity, water consumption and others, and (ii) create an improved interior environment to support user performance. Also, the modular characteristics of the individual panel elements facilitate future renovation and/or improvement as they may be simply disconnected and replaced, avoiding the demolition of traditional construction renovation. The building 100 incorporate technologies that allow the building to be used in a large variety of situations and environments without requiring redesign of the building structure or components. Further, the panels 20, roof trusses 110, roof joists 115, major and minor columns 114, 116, and the structure of the sled 102, shed 104, and expansion modules 106 combine to form a structural frame of modular building 100 that can be easily transported onto a building site with essentially all labor-intensive and inspection-intensive work—such as welding, drilling and cutting—already completed. This allows the modular building 100 composed of the sled 102, shed 104, and optional expansion modules 106 to be quickly assembled on the site. The pre-manufactured structural components comprise a “kit of parts” that only needs to be joined or partially assembled without extensive on-site alterations to provide a high-performance structure with an adaptable interior configuration. This reduces the impact of the site preparations in grid-connected utility requirements. The structures also reduce risks associated with improper assembly by requiring only minimal skill levels for assembly and equipment usage. The assembled modular building 100 can also withstand the vertical and lateral forces generated in earthquakes and storms. Further, the modular building 100 also reduces on-site construction waste as the precision of the engineering and fabrication process and defined means of on-site installation reduce the material waste that typifies traditional on-site construction. Any excess material is collected at the factory in which the panels are built for recycling.

While illustrative embodiments of the multifunctional panel 20 are described in the present application, it should be understood that other embodiments are also possible. For example, the multifunctional panel 20 can have other shapes and structures and can be made from other materials as would be apparent to those of ordinary skill in the art. Thus, the scope of the claims should not be limited to the illustrative embodiments described herein.

1. A multifunctional panel for a building, the panel comprising:
(a) a exterior surface that is weather resistant;
(b) an interior surface that opposes the weather resistant exterior surface;
(c) an insulative body between the interior and exterior surfaces;
(d) one or more sensors to measure an interior condition in the interior of the building and to measure an exterior condition in the exterior of the building, and generate a sensor signal in response to the difference between the measured interior and exterior conditions; and
(e) a signal coupler to transmit the sensor signal to other multifunctional panels, receive an input signal from another multifunctional panel, or pass power to power a device in or about the insulative body.

2. A panel according to claim 1 wherein a sensor comprises a temperature sensor.

3. A panel according to claim 2 wherein the temperature sensor includes any one of a thermocouple, resistance temperature detector, or bimetallic sensor.

4. A panel according to claim 1 wherein a sensor comprises a humidity sensor.

5. A panel according to claim 1 wherein a sensor comprises an air quality sensor.

6. A panel according to claim 1 wherein a sensor comprises a sound sensor.

7. A panel according to claim 1 wherein a sensor comprises at least one light sensor.

8. A panel according to claim 7 wherein a first light sensor is mounted on the interior surface to measure an ambient light intensity of the interior of a building, and a second light sensor is mounted on the exterior surface to measure an ambient light intensity of the exterior of the building.

9. A panel according to claim 1 comprising an internal or external controller and the signal coupler is capable of transmitting or receiving a signal to or from the controller to control a device.

10-12. (canceled)

13. A panel according to claim 1 wherein the interior surface comprises a fungible composition panel.

14. A multifunctional panel for a building, the panel comprising:
(a) an insulative body comprising an energy storage device having a pair of terminals; and
(b) opposing interior and exterior surfaces, the exterior surface including a photovoltaic array comprising a plurality of photovoltaic cells connected to one another, and a pair of output terminals that are electrically coupled to the terminals of the battery.

15. A panel according to claim 14 comprising an internet device having an internet protocol address and capable of enabling communications amongst devices within the insulative body, devices in other panels, or with a controller.

16. A panel according to claim 14 comprising at least one light mounted on the interior surface and electrically coupled to the output terminals of the photovoltaic array.

17. A panel according to claim 16 wherein the light comprises a direct current light.

18. A panel according to claim 14 comprising a light sensor mounted on the interior surface to provide a light signal to a light in the modular building.

19. A panel according to claim 13 further comprising a plurality sensors to measure an interior condition in the interior of the building and an exterior condition in the exterior of the building and generate a sensor signal in response to the differential between the measured interior and exterior conditions.

20. A multifunctional panel for a building, the panel comprising:
(a) an exterior surface that is weather resistant;
(b) an interior surface that opposes the exterior surface;
(c) an insulative body between the interior and exterior surfaces;
(d) a first sensor to measure an interior condition in the interior of the building and generate an interior-condition signal;
(e) second sensor to measure an exterior condition in the exterior of the building and generate an exterior-condition signal; and
(f) a switch to a turn a device on or off in response to the interior-condition signal, exterior-condition signal, or both.

21. A panel according to claim 20 comprising a differential signal generator to receive the interior-condition signal and exterior-condition signal and generate a differential signal in response to two signals.

22. A panel according to claim 20 comprising a signal coupler to transmit any one of the interior-condition or exterior-condition signal to other panels or to a controller, pass a switch signal from the switch to an external device in another panel, or pass power to power a device in or about the insulative body.

23. A panel according to claim 1 wherein a sensor comprises at least one of a temperature sensor, humidity sensor, air quality sensor, sound sensor, or light sensor.

24-27. (canceled)
